(19) United States
(12) Patent Application Publication
(10) Pub. No.: US 2022/0302403 A1
(43) Pub. Date: Sep. 22, 2022

(54) LIGHT-EMITTING DEVICE AND DISPLAY PANEL

(71) Applicant: YUNGU (GU'AN) TECHNOLOGY CO., LTD., Langfang (CN)

(72) Inventors: Mengyu LIU, Langfang (CN); Yu GAO, Langfang (CN); Zhi HUANG, Langfang (CN)

(73) Assignee: YUNGU (GU'AN) TECHNOLOGY CO., LTD., Langfang (CN)

(21) Appl. No.: 17/831,967

(22) Filed: Jun. 3, 2022

Related U.S. Application Data
(63) Continuation of application No. PCT/CN2021/088792, filed on Apr. 21, 2021.

(30) Foreign Application Priority Data
Jun. 11, 2020 (CN) 202010531637.9

(51) Int. Cl. H01L 51/50

(52) U.S. Cl. CPC H01L 51/5004; H01L 51/5012; H01L 51/5056; H01L 51/5096; H01L 2251/552

(57) ABSTRACT

A light-emitting device and a display panel. The light-emitting device includes a hole transport layer, an energy level adjustment layer, and a light-emitting layer stacked on each other. A first difference exists between an average activation energy of the hole transport layer and an average activation energy of the energy level adjustment layer, a second difference exists between the average activation energy of the energy level adjustment layer and an average activation energy of host material in the light-emitting layer, and an absolute value of the first difference and an absolute value of the second difference are greater than 0 eV.

### CROSS-REFERENCE

The present application is a continuation application of International (PCT) patent application No. PCT/CN2021/088792, filed on Apr. 21, 2021, which claims foreign priority of Chinese Patent Application No. 202010531637.9, filed on Jun. 11, 2020, in the China National Intellectual Property Administration, the entire contents of which are hereby incorporated by reference in their entireties.

### FIELD

The present disclosure relates to the technical field of display, and in particular to a light-emitting device and a display panel.

### BACKGROUND

Life of a blue light-emitting device, life of a green light-emitting device and life of a red light-emitting device in an organic light-emitting diode (OLED) display panel are inconsistent to each other. In response to the OLED display panel being lit for a long time, there is a problem that a color of white light changes. For example, generally speaking, the life of the blue light-emitting device is relatively short, therefore the OLED display panel may be turned red, green or yellow after being used for a long time.

In order to solve the problem above, in the related art, commonly used methods include adjusting an opening area of the blue light-emitting device, an opening area of the green light-emitting device, and an opening area of the red light-emitting device, so as to reduce life level differences between the three. However, from a process point of view, a ratio of the opening area of the blue light-emitting device, a ratio of the opening area of the green light-emitting device and a ratio of the opening area of the red light-emitting device cannot be enlarged or reduced indefinitely. Therefore, there is a need to find another way to improve the life of light-emitting device.

### SUMMARY

A light-emitting device and a display panel are provided in the embodiments of the present disclosure, to improve the life of the light-emitting device by way of activation energy matching.

To solve the above technical problem, according to a first aspect of some embodiments of the present disclosure, a light-emitting device is provided and includes a hole transport, an energy level adjustment layer and a light-emitting layer stacked on each other. There is a first difference between an average activation energy of the hole transport layer and an average activation energy of the energy level adjustment layer. There is a second difference between the average activation energy of the energy level adjustment layer and an average activation energy of a host material in the light-emitting layer. An absolute value of the first difference and an absolute value of the second difference are greater than 0 eV.

To solve the above technical problem, according to a second aspect of an embodiment of the present disclosure, a display panel is provided and includes the above-mentioned light-emitting device.

The beneficial effect of some embodiments of the present disclosure is that, in contrast to the related art, in the light-emitting device provided by some embodiments of the present disclosure, there is a non-zero first difference between an average activation energy of the hole transport layer and an average activation energy of the energy level adjustment layer; there is a non-zero second difference between the average activation energy of the energy level adjustment layer and an average activation energy of host material in the light-emitting layer. In the embodiments of the present disclosure, the average activation energy is used to measure energy level matching in the light-emitting device, so that injection efficiency and migration efficiency of holes may be improved, the life of the light-emitting device may be prolonged, and light-emitting efficiency of the light-emitting device may be improved.

### BRIEF DESCRIPTION OF THE DRAWINGS

To illustrate the technical solutions more clearly in the embodiments of the present disclosure, the following will be briefly introduce the attached drawings required to be used in the description of the embodiments. It is obvious that the attached drawings in the following description are only some embodiments of the present disclosure, and for those skilled in the related art, without creative work, can also obtain other attached drawings based on these drawings.

FIG. 1 is a structural schematic view of a light-emitting device according to an embodiment of the present disclosure.

FIG. 2 is a color coordinate schematic diagram of an experiment example 1 and a comparative example 1 changing with time.

FIG. 3 is a structural schematic view of the light-emitting device according to another embodiment of the present disclosure, where an electron transport layer and an energy-level-matching layer are added between a light-emitting layer and a cathode shown in FIG. 1, and the energy-level-matching layer is in contact with the light-emitting layer.

FIG. 4 is a schematic diagram of a cyclic voltammetry curve of the energy-level-matching layer in a comparative example 2.

FIG. 5 is a schematic diagram of a cyclic voltammetry curve of the energy-level-matching layer in an experimental example 2.

FIG. 6 is a curve schematic diagram of a light-emitting efficiency of the light-emitting device corresponding to the comparative example 2 changing with temperature.

FIG. 7 is a curve schematic diagram of a light-emitting efficiency of the light-emitting device corresponding to the experimental example 2 changing with temperature.

FIG. 8 is a color coordinate schematic diagram of the experiment example 2 and the comparative example 2 changing with a temperature.

FIG. 9 is a structural schematic view of a display panel according to an embodiment of the present disclosure.

### DETAILED DESCRIPTION

The technical solutions in the embodiments of the present disclosure will be clearly and completely described below in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the related art without making creative labor fall within the scope of the present disclosure.

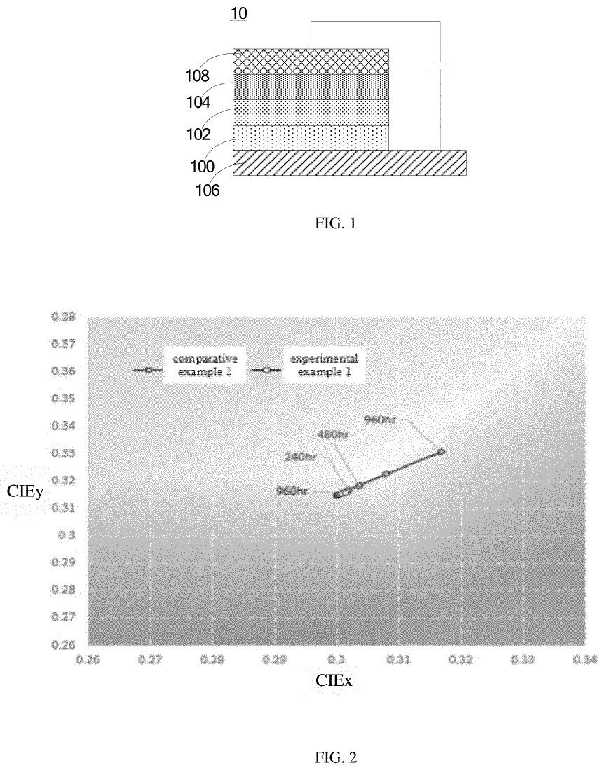

Referring to FIG. 1, FIG. 1 is a structural schematic view of a light-emitting device according to an embodiment of the present disclosure. The light-emitting device 10 includes a hole transport layer 100, an energy level adjustment layer 102, and a light-emitting layer 104 stacked on each other. There is a first difference ΔEa1 between an average activation energy of the hole transport layer 100 and an average activation energy of the energy level adjustment layer 102. There is a second difference ΔEa2 between the average activation energy of the energy level adjustment layer 102 and an average activation energy of a host material in the light-emitting layer 104. An absolute value of the first difference ΔEa1 and an absolute value of the second difference ΔEa2 are greater than 0 eV.

In some embodiments, activation energy refers to energy required for a certain substance to become an activated molecule. The lower the activation energy, the lower the potential barrier the substance needs to overcome. The activation energy may be calculated by using the following Arrhenius formula: Ea=E0+mRT. In the formula, Ea represents the activation energy, E0 and m represent temperature-independent constants, T represents a temperature, and R represents the molar gas constant. In addition, a unit of the activation energy obtained by the above formula is Joule J. The unit of the activation energy may be converted into electron volt eV through a simple conversion formula. In some embodiments, the conversion formula is: 1 eV=1.602176565*10⁻¹⁹ J.

In the case where the hole transport layer 100, the energy level adjustment layer 102, and the light-emitting layer 104 are each formed by a single substance, activation energy Ea of the single substance is the average activation energy of the hole transport layer 100, the average activation energy of the energy level adjustment layer 102, or the average activation energy of the light-emitting layer 104.

In the case where the hole transport layer 100, the energy level adjustment layer 102, and the light-emitting layer 104 are each formed by mixing multiple substances, a calculation process of the average activation energy of the hole transport layer 100 corresponding to the multiple substances or the average activation energy of the energy level adjustment layer 102 corresponding to the multiple substances, or the average activation energy of the light-emitting layer 104 corresponding to the multiple substances, may be the following. Firstly, a product value of the activation energy Ea of each of the multiple substances and a corresponding molar mass fraction is obtained. Then, a sum of each of product values above is obtained to obtain the average activation energy. In other embodiments, a thermogravimetric analysis process may be performed directly on a whole of the hole transport layer 100, a whole of the energy level adjustment layer 102, or a whole of the light-emitting layer 104, and corresponding average activation energy may be obtained by calculating directly based on results of the thermogravimetric analysis process. In some embodiments, the thermogravimetric analysis process refers to a method for obtaining a changing relationship of a mass of a substance with a temperature (or time) under a program-controlled temperature. After a thermogravimetric curve is obtained by thermogravimetric analysis technique, the average activation energy may be obtained through differential subtraction method (Freeman-Carroll) or integral method (OWAZa).

hi the related art, the Highest Occupied Molecular Orbital (HOMO)/the Lowest Occupied Molecular Orbital (LOMO) is generally used to measure an energy-level matching situation of the light-emitting device 10. The HOMO/LOMO only considers an injection efficiency of holes. However, in some embodiments of the present disclosure, the average activation energy is used to measure the energy-level matching situation in the light-emitting device 10. In this way, the injection efficiency and a migration efficiency of the holes may be comprehensively considered. Compared with a traditional way of HOMO/LOMO, the life of the light-emitting device 10 may be prolonged, and light-emitting efficiency of the light-emitting device 10 may be improved.

hi the present embodiment, the energy level adjustment layer 102 mentioned above may be an electron blocking layer, and a material of the energy level adjustment layer 102 may be a single aromatic amine structure containing a spirofluorene group, a single aromatic amine structure containing a spiro ring unit, or the like. A design way of the energy level adjustment layer 102 mentioned above may not only achieve a purpose of the energy level matching, but also block electrons of a cathode, so as to further improve the light-emitting efficiency of the light-emitting device 10.

hi some embodiments, a material of the hole transport layer 100 may be poly-p-phenylene vinylene, polythiophene, polysilane, triphenylmethane, triarylamine, hydrazone, pyrazoline, oxazole, carbazole, butadiene, etc.

hi an embodiment, in response to the light-emitting layer 104 being a blue light-emitting layer, the absolute value of the first difference ΔEa1 is greater than or equal to the absolute value of the second difference ΔEa2. In this way, the number of the holes concentrated at an interface between the energy level adjustment layer 102 and the light-emitting layer 104 may be less than the number of the holes at an interface between the hole transport layer 100 and the energy level adjustment layer 102, so that a possibility of the holes being over-concentrated at the interface of the light-emitting layer 104 may be reduced, and a speed of deterioration of light-emitting material of the light-emitting layer 104 may be reduced, so as to improve the life of the light-emitting device 10.

In an application scenario, when the light-emitting layer 104 is the blue light-emitting layer, the absolute value of the first difference ΔEa1 is greater than or equal to 0.1 eV and less than or equal to 0.15 eV, and the absolute value of the second difference ΔEa2 is greater than or equal to 0.05 eV and less than or equal to 0.1 eV. For example, the absolute value of the first difference ΔEa1 may be 0.12 eV, 0.14 eV and so on, and the absolute value of the second difference ΔEa2 may be 0.06 eV, 0.08 eV and so on. In this design way of ranges of the first difference ΔEa1 and the second difference ΔEa2 mentioned above, life of the blue light-emitting layer may be effectively improved, and life difference between the blue light-emitting layer and the red light-emitting layer and life difference between the blue light-emitting layer and the green light-emitting layer may be reduced, so as to reduce an occurrence possibility of color shift.

hi some embodiments, a difference between the average activation energy of the energy level adjustment layer 102 and the average activation energy of the hole transport layer 100 is in a range of −0.1 eV to −0.2 eV (for example, −0.15 eV, −0.18 eV). A difference between the average activation energy of the blue light-emitting layer and the average activation energy of the hole transport layer 100 is in a range of −0.2 eV to −0.3 eV (for example, −0.25 eV, −0.28 eV). In this design way mentioned above, a blue light-emitting device may have a longer life and a higher light-emitting efficiency.

In order to verify an actual effect of the design way above, a comparative example 1 and an experimental example 1 are designed in the following. The absolute value of the first difference ≢Ea1 between the average activation energy of the hole transport layer 100 and the energy level adjustment layer 102 in the experimental example 1 is 0.1 eV, the absolute value of the second difference ΔEa2 between the average activation energy of the energy level adjustment layer 102 and the average activation energy of the host material in the blue light emitting layer 104 is 0.05 eV. The difference between the comparative example 1 and the experimental example 1 is that a light-emitting device corresponding to the comparative example 1 does not include the energy level adjustment layer 102. Performance test results of the light-emitting device corresponding to the comparative example 1 and a light-emitting device corresponding to the experimental example 1 are shown in Table 1 below.

TABLE 1
comparison table of performance test of the light-emitting device
corresponding to the comparative example 1 and the light-emitting
device corresponding to the experimental example 1

| | | | Von@1nits | Vd | BI. (cd/A/ | LT95@1200nit |
|---|---|---|---|---|---|---|
| | CIEx | CIEy | (V) | (V) | CIEy) | (hrs) |
| comparative | 0.140 | 0.042 | 3.02 | 3.87 | 161.9 | 180 |
| example 1 | | | | | | |
| experimental | 0.141 | 0.042 | 3.01 | 3.87 | 128.8 | 129 |
| example 1 | | | | | | |

It can be seen from the above Table 1 that the color coordinates CIEx and CIEy of light emitted by the light-emitting device corresponding to the experimental example 1 are basically the same with the color coordinates CIEx and CIEy of light emitted by the light-emitting device corresponding to the comparative example 1. And the Von@1 nits and Vd of the light-emitting device corresponding to the experimental example 1 are also basically the same with the Von@1 nits and Vd of the light-emitting device corresponding to the comparative example 1. The Von@1 nits refers to a voltage value under a tiny brightness of 1 nits, and Vd refers to a voltage value under an operating brightness of 1200 nits. As for the lifetime (LT95@1200 nit), a continuous electric current test (DC) was conducted with the initial brightness of 1200 nits, and LT95@1200 nit refers to a period of time taken for which the luminance was reduced to 95% as compared with the luminance at the time of starting the test. A BI value of the experimental example 1 is increased by 20% relative to a BI value of the comparative example 1. Duration of the experimental example 1 at the brightness of 1200 nits is increased by 28% relative to the duration of the comparative example 1. BI refers to cd/A/CIEy, cd/A refers to the light-emitting efficiency, and CIEy refers to a coordinate of CIExy1931. Since the light-emitting efficiency cd/A of blue light is easily affected by the CIEy value, the BI value is generally used to define blue light efficiency in the related art. It can be seen from the performance testing results above that the light-emitting efficiency and the light-emitting life of the blue light-emitting device may be improved significantly through a solution adopted in the embodiments of the present disclosure.

In some embodiments, referring to FIG. 2, FIG. 2 is a color coordinate schematic diagram of the experiment example 1 and the comparative example 1 changing with time. It can be clearly seen from FIG. 2 that, compared with the comparative example 1, the life of the blue light-emitting device in experimental example 1 is extended with increasing of time, and a change in white light color coordinates decreases with the increasing of the time.

In an application scenario, in response to the light-emitting layer 104 being the blue light-emitting layer, and the blue light-emitting layer including a blue light-emitting host material BH and a blue light-emitting dopant material BD, there is a third difference ΔEa3 between the average activation energy of the energy level adjustment layer 102 and an average activation energy of the blue light-emitting dopant material BD, and an absolute value of the third difference ΔEa3 is less than the absolute value of the second difference ΔEa2. A main function of the blue light-emitting host material BH is to transfer energy and reduce a possibility of triplet energy being annihilated, and a main function of the blue light-emitting dopant material BD is to emit light. In response to the blue light-emitting layer emitting the light, the energy is transferred between the blue light-emitting host material BH and the blue light-emitting dopant material BD. In this design way of the average activation energy mentioned above, it is easier for holes transported by the energy level adjustment layer 102 to arrive at the blue light-emitting dopant material BD, and the energy may be effectively transported to the blue light-emitting dopant material BD from the blue light-emitting host material BH, so as to reduce a possibility of energy backflow and ensure the light-emitting efficiency.

In the present embodiment, a difference between an average activation energy of the blue light-emitting host material BH and the average activation energy of the hole transport layer 100 is in a range of −0.2 eV to −0.3 eV, and a difference between an average activation energy of the blue light-emitting dopant material BD and the average activation energy of the hole transport layer 100 is in a range of −0.2 eV to −0.3 eV. The blue light-emitting host material BH may be a carbazole group derivative, an aryl silicon derivative, an aromatic derivative, a metal complex derivative, etc. The blue light-emitting dopant material BD may be a fluorescent doping material (for example, porphyrin-based compounds, coumarin-based dyes, quinacridone-based compounds, arylamine-based compounds, etc.) or phosphorescent doping materials (for example, complexes containing metal iridium, etc.) and the like.

Further, in response to the absolute value of the second difference ΔEa2 being greater than or equal to 0.05 eV and less than 0.1 eV, the absolute value of the third difference ΔEa3 between the average activation energy of the energy level adjustment layer 102 and the average activation energy of the blue light-emitting dopant material BD is less than 0.05 eV. For example, the absolute value of the third difference ΔEa3 may be 0.04 eV, 0.03 eV, and so on. In this design way of the second difference ΔEa2 and the third difference ΔEa3 mentioned above, the light-emitting efficiency of the blue light-emitting layer may be effectively improved. For example, the design way of the second difference ΔEa2 is conducive to accumulating a certain number of holes and electrons. And the holes and the electrons may combine to form excitons to improve the light-emitting efficiency. The design way of the third difference ΔEa3 facilitates the injection of holes from the energy level adjustment layer 102 into the blue light-emitting dopant material BD.

In another embodiment, when the light-emitting layer 104 is a green light-emitting layer, the absolute value of the first difference ΔEa1 between the average activation energy of the hole transport layer 100 and the average activation energy of the energy level adjustment layer 102 is greater than or equal to 0.05 eV and less than or equal to 0.1 eV. The green light-emitting layer includes green light-emitting host material GH. The absolute value of the second difference ΔEa2 between the average activation energy of the energy level adjustment layer 102 and an average activation energy of the green light-emitting host material GH in the light-emitting layer 104 is greater than or equal to 0.1 eV and less than or equal to 0.15 eV. For example, the absolute value of the first difference ΔEa1 may be 0.06 eV, 0.08 eV, etc., and the absolute value of the second difference ΔEa2 may be 0.14 eV, 0.13 eV, etc. In this design way of ranges of the first difference ΔEa1 and the second difference ΔEa2 mentioned above, the life of the green light-emitting device may be effectively extended, and a light-emitting efficiency of the green light-emitting device may be effectively improved.

In an application scenario, the green light-emitting layer may include the green light-emitting host material GH and a green light-emitting dopant material GD. There is a third difference ΔEa3 between the average activation energy of the energy level adjustment layer 102 and an average activation energy of the green light-emitting dopant material GD, and an absolute value of the third difference ΔEa3 is less than 0.05 eV. An absolute value of a difference between an average activation energy of the green light-emitting host material GH and the average activation energy of the green light-emitting dopant material GD is in a range of 0.08-0.12 eV. For example, the average activation energy of the green light-emitting host material GH has a difference of 0.15 eV to 0.2 eV relative to the average activation energy of the hole transport layer 100, and the average activation energy of the green light-emitting dopant material GD has a difference of 0.05 eV to 0.15 eV relative to the average activation energy of the hole transport layer 100. The average activation energy of the energy level adjustment layer 102 has a difference of 0.05 eV to 0.1 eV (for example, 0.06, 0.08 eV) relative to the average activation energy of the hole transport layer 100.

In yet another embodiment, in response to the light-emitting layer being a red light-emitting layer, the absolute value of the first difference ΔEa1 between the average activation energy of the hole transport layer 100 and the average activation energy of the energy level adjustment layer 102 is greater than or equal to 0.1 eV and less than or equal to 0.15 eV. The red light-emitting layer includes red light-emitting host material RH. The absolute value of the second difference ΔEa2 between the average activation energy of the energy level adjustment layer 102 and an average activation energy of the red light-emitting host material RH in the light-emitting layer 104 is less than 0.05 eV. For example, the absolute value of the first difference ΔEa1 mentioned above may be 0.12 eV, 0.14 eV, etc., and the absolute value of the second difference ΔEa2 mentioned above may be 0.04 eV, 0.03 eV, etc. In this design way of ranges of the first difference ΔEa1 and the second difference ΔEa2 mentioned above, life of the red light-emitting device may be effectively extended, and a light-emitting efficiency of the red light-emitting device may be effectively improved.

In an application scenario, the red light-emitting layer may also include the red light-emitting host material RH and a red light-emitting dopant material RD. There is a third difference ΔEa3 between the average activation energy of the energy level adjustment layer 102 and an average activation energy of the red light-emitting dopant material RD, and an absolute value of the third difference ΔEa3 is less than 0.05 eV. An absolute value of a difference between an average activation energy of the red light-emitting host material RH and the average activation energy of the red light-emitting dopant material RD is in a range of 0.08-0.12 eV. For example, the average activation energy of the red light-emitting host material RH has a difference of 0.20 eV to 0.25 eV relative to the average activation energy of the hole transport layer 100, and the average activation energy of the red light-emitting dopant material RD has a difference of 0.10 eV to 0.15 eV relative to the average activation energy of the hole transport layer 100. The average activation energy of the energy level adjustment layer 102 has a difference of 0.10 eV to 0.15 eV (for example, 0.12, 0.14 eV) relative to the average activation energy of the hole transport layer 100.

In some embodiments, in response to the energy level adjustment layer 102 being an electron-blocking layer, the light-emitting device provided by some embodiments of the present disclosure may further include a first energy level layer located between the electron-blocking layer and the light-emitting layer 104. An average activation energy of the first energy level layer is between an average activation energy of the electron-blocking layer and the average activation energy of the light-emitting layer 104. In this design way, life loss of the light-emitting device caused by an impact at an interface between the electron-blocking layer and the light-emitting layer 104 may be reduced, so that the life of the light-emitting device may be extended.

In other embodiments, the light-emitting device provided by some embodiments of the present disclosure may further include a second energy level layer located between the electron-blocking layer and the hole transport layer 100. An average activation energy of the second energy level layer is between an average activation energy of the electron-blocking layer and the average activation energy of the hole transport layer 100. In this design way, life loss of the light-emitting device caused by an impact at an interface between the electron-blocking layer and the hole transport layer 100 may be reduced, so that the life of the light-emitting device may be extended.

In addition, referring to FIG. 1 again, the light-emitting device 10 provided in FIG. 1 is a single-layer device and may include a cathode 108 and an anode 106. Of course, in other embodiments, an electron transport layer may also be added between the light-emitting layer 104 and the cathode 108 shown in FIG. 1.

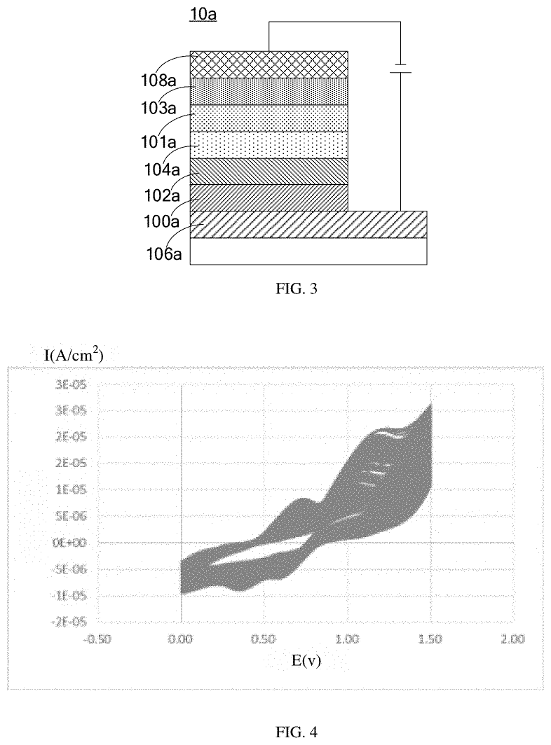

hi other embodiments, as shown in FIG. 3, FIG. 3 is a structural schematic view of the light-emitting device according to another embodiment of the present disclosure. In addition to structure layers shown in FIG. 1, the light-emitting device 10a further includes an electron transport layer 103a and an energy-level-matching layer 101a added between the light-emitting layer 104a (that is, 104 shown in FIG. 1) and the cathode 108a (that is, 108 shown in FIG. 1). The energy-level-matching layer 101a is in contact with the light-emitting layer 104a. A structure design of the light-emitting device 10a is relatively simple, and the light-emitting device 10a is easy to manufacture. There is a fourth difference ΔEa4 between an average activation energy of the electron transport layer 103a and an average activation energy of the energy-level-matching layer 101a. There is a fifth difference ΔEa5 between the average activation energy of the energy-level-matching layer 101a and the average activation energy of the host material in the light-emitting layer 104a, and an absolute value of the fourth difference ΔEa4 is less than an absolute value of the fifth difference ΔEa5.

In the related art, the Highest Occupied Molecular Orbital (HOMO)/the Lowest Occupied Molecular Orbital (LOMO) is generally used to measure an energy-level matching situation of the light-emitting device 10a. The HOMO/LOMO only considers the injection efficiency of electrons or holes. However, in the embodiments of the present disclosure, the average activation energy is used to measure the energy-level matching situation in the light-emitting device 10a. In this way, on the basis of comprehensively considering the injection efficiency and the migration efficiency of the holes, the temperature, the injection efficiency of the electrons and the migration efficiency of the electrons may be further considered. Compared with the traditional way of HOMO/LOMO, the life of the light-emitting device 10a may be prolonged, so as to improve the light-emitting efficiency of the light-emitting device 10a and reduce a possibility of the light-emitting efficiency of the light-emitting device 10a changing greatly with the temperature. And in this design way, through a design method of the activation energy on two sides for the electrons and the holes, a probability of the electrons accumulating on a specific interface may be reduced, a higher efficient hole/electron combination may be achieved, and a state that the hole/electron combination changes with current may be reduced.

In the present embodiment, the energy-level-matching layer 101a may be a hole-blocking layer. A material of the energy-level-matching layer 101a may be at least one of 2,9-dimethyl-4,7-diphenyl-1,10-phenanthroline BCP; 1,3,5-Tris(N-phenyl-2-benzimidazole)benzene TPBi; Tris(8-hydroxyquinoline)aluminum(III)Alq3; 8-hydroxyquinoline-lithium Liq; bis(2-methyl-8-Hydroxyquinoline)(4-phenylphenol)aluminum(III)BAlq; 3-(biphenyl-4-yl)-5-(4-tert-butylphenyl)-4-phenyl-4H-1,2,4-triazole TAZ and the like. The design way of the energy-level-matching layer 101a mentioned above may not only achieve a purpose of energy level matching, but also may block holes of the anode 106a, so as to further improve the light-emitting efficiency of the light-emitting device 10a.

Further, in response to selecting the material of the energy-level-matching layer 101a, a material with a current changing rate less than 1% after a cyclic voltammetry test may be selected. In some embodiments, a temperature of the cyclic voltammetry test may be a room temperature or higher than the room temperature. In this design way, a performance stability of the energy-level-matching layer 101a under a long-term operation and the corresponding temperature may be ensured, so as to improve a problem that the light-emitting efficiency changes with the temperature at a low gray scale.

In an embodiment, the light-emitting layer 104a is a blue light-emitting layer, and the absolute value of the fourth difference ΔEa4 between the average activation energy of the electron transport layer 103a and the average activation energy of the energy-level-matching layer 101a is less than 0.05 eV. The absolute value of the fifth difference ΔEa5 between the average activation energy of the energy-level-matching layer 101a and the average activation energy of the host material in the light-emitting layer 104a is greater than or equal to 0.1 eV and less than or equal to 0.15 eV. For example, the absolute value of the fourth difference ΔEa4 may be 0.02 eV, 0.04 eV and so on. The absolute value of the fifth difference ΔEa5 may be 0.12 eV, 0.14 eV and so on. In this design way of ranges of the fourth difference ΔEa4 and the fifth difference ΔEa5 above, the light-emitting efficiency of the blue light-emitting layer at different temperatures may be improved effectively, and difference in the light-emitting efficiency at different temperatures may be reduced, so as to reduce an occurrence rate of white light shift.

In an application scenario, the average activation energy of the energy-level-matching layer 101a has a difference of −0.05 eV to 0 eV (eg, −0.02 eV, −0.03 eV, etc.) relative to the average activation energy of the electron transport layer 103a. The average activation energy of the host material of the blue light-emitting layer has a difference of 0.05 eV to 0.15 eV (eg, 0.11 eV, 0.14 eV, etc.) relative to the average activation energy of the electron transport layer 103a. In this design way above, the life of the light-emitting device 10a may be relatively long and the light-emitting efficiency of the light-emitting device 10a may be relatively high.

In one application scenario, the blue light-emitting layer includes blue light-emitting host material BH and blue light-emitting dopant material BD. There is a sixth difference ΔEa6 between an average activation energy of the blue light-emitting dopant material BD and the average activation energy of the energy-level-matching layer 101a, and an absolute value of the sixth difference ΔEa6 is less than the absolute value of the fifth difference ΔEa5. In some embodiments, a main function of the blue light-emitting host material BH is to transfer an energy and reduce a possibility of triplet energy being annihilated, and a main function of the blue light-emitting dopant material BD is to emit light. In response to the blue light-emitting layer emitting the light, the energy is transferred between the blue light-emitting host material BH and the blue light-emitting dopant material BD. In this design way of the average activation energy mentioned above, it is easier for electrons transported by the energy-level-matching layer 101a to arrive at the blue light-emitting dopant material BD, and the energy may be effectively transported to the blue light-emitting dopant material BD from the blue light-emitting host material BH, so as to reduce a possibility of energy backflow and ensure the light-emitting efficiency.

Further, the absolute value of the sixth difference ΔEa6 between the average activation energy of the blue light-emitting dopant material BD and the average activation energy of the energy-level-matching layer 101a is less than 0.05 eV. For example, the absolute value of the sixth difference ΔEa6 may be 0.04 eV, 0.02 eV, etc. Meanwhile, a difference between the average activation energy of the blue light-emitting dopant material BD and the average activation energy of the blue light-emitting host material BH may be between 0.05 eV and 0.1 eV, for example, 0.06 eV, 0.08 eV, and the like. In this design way of the sixth difference ΔEa6 and the fifth difference ΔEa5, the light-emitting efficiency of the blue light-emitting layer may be effectively improved. For example, the design way of the sixth difference ΔEa6 above is conducive to accumulating a certain number of holes and electrons. And the holes and the electrons may combine to form excitons to improve the light-emitting efficiency. The design way of the fifth difference ΔEa5 above may facilitate the efficient energy transfer of the blue light-emitting host material BH to the blue light-emitting dopant material BD, so that the possibility of energy backflow may be reduced and the light-emitting efficiency may be ensured.

In order to verify actual effect of the design way above, a comparative example 2 and an experimental example 2 are designed in the following.

The activation energy of each layer in the comparative example 2 is designed as follows. The absolute value of the average activation energy difference between the blue light-emitting host material BH and the blue light-emitting dopant material BD is 0.02 eV. The absolute value of the average activation energy difference between the blue light-emitting dopant material BD and the energy-level-matching layer 101a is 0.02 eV. The absolute value of the average activation energy difference between the blue light-emitting host material BH and the energy-level-matching layer 101a is 0.03 eV. The absolute value of the average activation energy difference between the energy-level-matching layer 101a and the electron transport layer 103a is 0.03 eV. Specifically, in the comparative example 2, an activation energy difference of the blue light-emitting host material BH relative to the electron transport layer 103a, an activation energy difference of the blue light-emitting dopant material BD relative to the electron transport layer 103a, and an activation energy difference of the energy-level-matching layer 101a relative to the electron transport layer 103a are all positive values.

The activation energy of each layer in the experimental example 2 is designed as follows. The absolute value of the average activation energy difference between the blue light-emitting host material BH and the blue light-emitting dopant material BD is 0.1 eV. The absolute value of the average activation energy difference between the blue light-emitting dopant material BD and the energy-level-matching layer 101a is 0.04 eV. The absolute value of the average activation energy difference between the blue light-emitting host material BH and the energy-level-matching layer 101a is 0.11 eV. The absolute value of the average activation energy difference between the energy-level-matching layer 101a and the electron transport layer 103a is 0.02 eV. Specifically, in the experimental example 2, an activation energy difference of the blue light-emitting host material BH relative to the electron transport layer 103a and an activation energy difference of the blue light-emitting dopant material BD relative to the electron transport layer 103a are all positive values. Whereas, an activation energy difference of the energy-level-matching layer 101a relative to the electron transport layer 103a is a negative value.

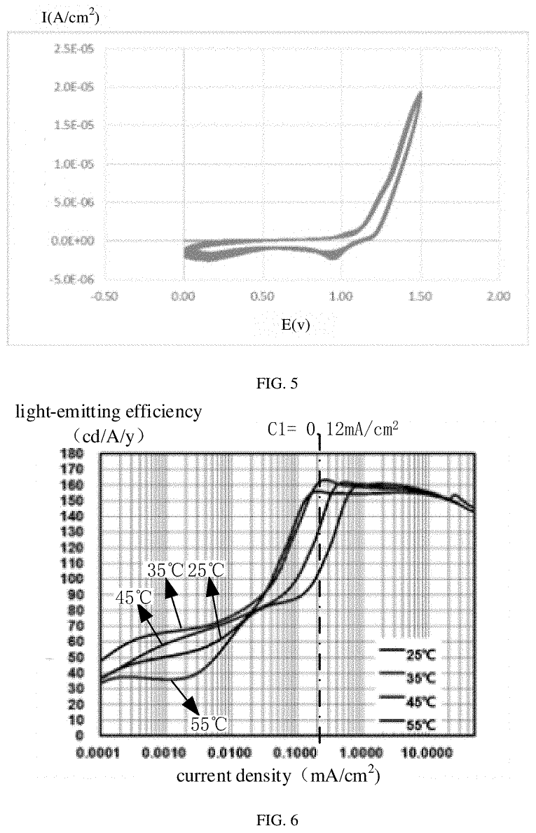

Referring to FIG. 4 and FIG. 5, FIG. 4 is a schematic diagram of a cyclic voltammetry curve of the energy-level-matching layer 101a in the comparative example 2. FIG. 5 is a schematic diagram of a cyclic voltammetry curve of the energy-level-matching layer 101a in the experimental example 2. It can be seen from the FIG. 4 and FIG. 5 that a current change of the material of energy-level-matching layer 101a in the experimental example 2 is relatively small after undergoing 100 cycles of cyclic voltammetry tests. It may be found by calculation that a current change rate of the material of energy-level-matching layer 101a in the comparative example 2 after undergoing the 100 cycles of cyclic voltammetry tests is 4.4%. While a current change rate of the material of energy-level-matching layer 101a in the experimental example 2 after undergoing the 100 cycles of cyclic voltammetry tests is only 0.5%.

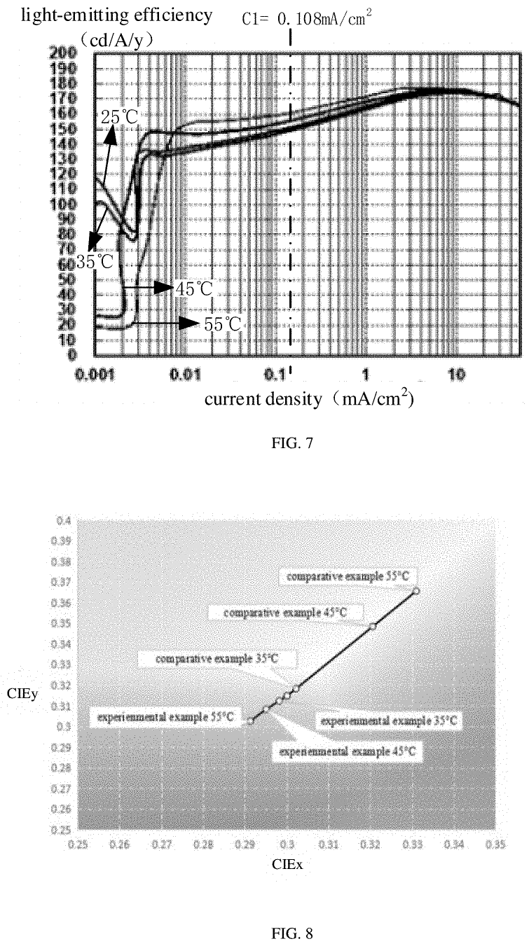

Referring to FIG. 6 and FIG. 7, FIG. 6 is a curve schematic diagram of a light-emitting efficiency of the light-emitting device corresponding to the comparative example 2 changing with temperature. FIG. 7 is a curve schematic diagram of a light-emitting efficiency of the light-emitting device corresponding to the experimental example 2 changing with temperature. It can be seen from the FIG. 6 and FIG. 7 that, a change of the light-emitting efficiency at various temperatures of the light-emitting device of the experimental example 2 is clearly less than a change of the light-emitting efficiency at the various temperatures of the light-emitting device of the comparative example 2. The light-emitting efficiency of the comparative example 2 is less than the light-emitting efficiency of the experimental example 2. In order to achieve the same displaying brightness, a driving current required by the comparative example 2 is greater than a driving current required by the experimental example 2. For example, as shown in FIG. 6 and FIG. 7, in order to achieve the same displaying brightness, a current density of 0.12 mA/cm² is required in the comparative example 2, while a current density of 0.108 mA/cm² is required in the experimental example 2.

Further, it may be found by comparison that, corresponding to the same current density of 0.12 mA/cm², the light-emitting efficiency of the light-emitting device in the comparative example 2 at 55° C. is reduced relative to the light-emitting efficiency of the light-emitting device in the comparative example 2 at 25° C. And the light-emitting efficiency at 55° C. of the light-emitting device in the comparative example 2 is 88.5% of the light-emitting efficiency of the light-emitting device in the comparative example 2 at 25° C. Corresponding to the same current density of 0.108 mA/cm², the light-emitting efficiency of the light-emitting device in the experimental example 2 at 55° C. is increased relative to the light-emitting efficiency of the light-emitting device in the experimental example 2 at 25° C. And the light-emitting efficiency of the light-emitting device in the experimental example 2 at 55° C. is 111.6% of the light-emitting efficiency of the light-emitting device in the experimental example 2 at 25° C.

Further, referring to FIG. 8, FIG. 8 is a color coordinate schematic diagram of the experiment example 2 and the comparative example 2 changing with a temperature. As shown in FIG. 8, relative to the comparative example 2, a change of the white light shift in the experiment example 2 with temperature is smaller.

The above-mentioned embodiments are provided for a situation that the light-emitting layer 104a is the blue light-emitting layer. Of course, the above-mentioned methods are also applicable to light-emitting layers of other colors.

For example, in response to the light-emitting layer 104a being the green light-emitting layer, the absolute value of the fourth difference ΔEa4 between the average activation energy of the energy-level-matching layer 101a and the average activation energy of the electron transport layer 103a is less than 0.05 eV. The absolute value of the fifth difference ΔEa5 between the average activation energy of the green light-emitting host material GH and the average activation energy of the energy-level-matching layer 101a is less than 0.05 eV. The absolute value of the difference between the average activation energy of the green light-emitting host material GH and the average activation energy of the green light-emitting dopant material GD is between 0.05 eV and 0.1 eV. The absolute value of the sixth difference ΔEa6 between the average activation energy of the green light-emitting dopant material GD and the average activation energy of the energy-level-matching layer 101a is less than 0.1 eV. In an embodiment, the energy-level-matching layer 101a has an average activation energy difference greater than 0 and less than 0.05 eV relative to the electron transport layer 103a. The green light-emitting host material GH has an average activation energy difference greater than −0.05 eV and less than 0 eV relative to the electron transport layer 103a. The green light-emitting dopant material GD has an activation energy difference greater than or equal to −0.1 eV and less than or equal to −0.05 eV relative to the green light-emitting host material GH.

For another example, in response to the light-emitting layer 104a being the red light-emitting layer, the absolute value of the fourth difference ΔEa4 between the average activation energy of the energy-level-matching layer 101a and the average activation energy of the electron transport layer 103a is less than 0.05 eV. The absolute value of the fifth difference ΔEa5 between the average activation energy of the red light-emitting host material RH of the red light-emitting layer and the average activation energy of the energy-level-matching layer 101a is less than 0.05 eV. The absolute value of the difference between the average activation energy of the red light-emitting host material RH and the average activation energy of the red light-emitting dopant material RD is between 0.08 eV and 0.12 eV. The absolute value of the sixth difference ΔEa6 between the average activation energy of the red light-emitting dopant material RD and the average activation energy of the energy-level-matching layer 101a is between 0.08 eV and 0.12 eV. In an embodiment, the energy-level-matching layer 101a has an average activation energy difference greater than 0 and less than 0.05 eV relative to the electron transport layer 103a. The red light-emitting host material RH has an average activation energy difference greater than 0 eV and less than 0.05 eV relative to the electron transport layer 103a. The red light-emitting dopant material RD has an activation energy difference greater than or equal to −0.1 eV and less than or equal to 0 eV relative to the red light-emitting host material RH.

In some embodiments, in response to the energy-level-matching layer 101a being the hole-blocking layer, the light-emitting device 10a provided by the embodiments of the present disclosure may further include a third energy level layer located between the hole-blocking layer and the light-emitting layer 104a. An average activation energy of the third energy level layer is between the average activation energy of the hole-blocking layer and the average activation energy of the light-emitting layer 104a. In this design way, a life loss of the light-emitting device 10a caused by an impact at an interface between the hole-blocking layer and the light-emitting layer 104a may be reduced, so that the life of the light-emitting device 10a may be extended.

In other embodiments, the light-emitting device 10a provided by some embodiments of the present disclosure may further include a fourth energy level layer located between the hole-blocking layer and the electron transport layer 103a. An average activation energy of the fourth energy level layer is between the average activation energy of the hole-blocking layer and the average activation energy of the electron transport layer 103a. In this design way, the life loss of the light-emitting device 10a caused by an impact at an interface between the hole-blocking layer and the electron transport layer 103a may be reduced, so that the life of the light-emitting device 10a may be extended.

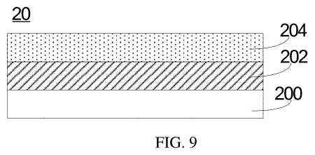

Referring to FIG. 9, FIG. 9 is a structural schematic view of a display panel according to an embodiment of the present disclosure. The display panel 20 provided by the embodiment of the present disclosure may include the light-emitting device mentioned in any one of the embodiments above. The display panel 20 may include an array substrate 200, a light-emitting device layer 202, an encapsulation layer 204 and the like stacked on each other. The light-emitting device layer 202 may include the light-emitting device mentioned in any one of the embodiments above. The light-emitting device may be a blue light-emitting device, a red light-emitting device, or a green light-emitting device.

In the present embodiment, in response to the light-emitting device layer 202 including the blue light-emitting device, the red light-emitting device, and the green light-emitting device, a hole transport layer of the blue light-emitting device, a hole transport layer of the red light-emitting device, and a hole transport layer of the green light-emitting device may be formed with the same material, while for energy level adjustment layers, different materials may be chosen according to the designed activation energy requirements. The design method may reduce a manufacturing difficulty. In other embodiments, the hole transport layer of the blue light-emitting device, the hole transport layer of the red light-emitting device, and the hole transport layer of the green light-emitting device may also be formed with different materials, which are not limited in the present disclosure.

The above descriptions are only the embodiments of the present disclosure, and are not intended to limit the patent scope of the present disclosure. Any equivalent structure or equivalent process transformation made by using the contents of the description and drawings of the present disclosure, or directly or indirectly applied to other related technology fields are similarly included within the patent protection scope of the present disclosure.

What is claimed is:

1. A light-emitting device, comprising a hole transport layer, an energy level adjustment layer, and a light-emitting layer arranged in a stacked manner, wherein an average activation energy of the hole transport layer and an average activation energy of the energy level adjustment layer have a first difference therebetween, the average activation energy of the energy level adjustment layer and an average activation energy of host material in the light-emitting layer have a second difference therebetween, and an absolute value of the first difference and an absolute value of the second difference are greater than 0 eV.

2. The light-emitting device according to claim 1, wherein the light-emitting layer comprises a blue light-emitting layer, and the absolute value of the first difference is greater than or equal to the absolute value of the second difference.

3. The light-emitting device according to claim 2, wherein the absolute value of the first difference is greater than or equal to 0.1 eV and less than or equal to 0.15 eV, and the absolute value of the second difference is greater than or equal to 0.05 eV and less than or equal to 0.1 eV.

4. The light-emitting device according to claim 3, wherein a difference between the average activation energy of the energy level adjustment layer and the average activation energy of the hole transport layer is in a range of −0.1 eV to −0.2 eV, and a difference between the average activation energy of the blue light-emitting layer and the average activation energy of the hole transport layer is in a range of −0.2 eV to −0.3 eV.

5. The light-emitting device according to claim 3, wherein the blue light-emitting layer comprises blue light-emitting host material and blue light-emitting dopant material, the average activation energy of the energy level adjustment layer and an average activation energy of the blue light-emitting dopant material have a third difference therebetween, and an absolute value of the third difference is less than the absolute value of the second difference.

6. The light-emitting device according to claim 5, wherein the absolute value of the third difference is less than 0.05 eV.

7. The light-emitting device according to claim 5, wherein a difference between an average activation energy of the blue light-emitting host material and the average activation energy of the hole transport layer is in a range of −0.2 eV to −0.3 eV, and a difference between an average activation energy of the blue light-emitting dopant material and the average activation energy of the hole transport layer is in a range of −0.2 eV to −0.3 eV.

8. The light-emitting device according to claim 1, wherein the light-emitting layer comprises a green light-emitting layer, the absolute value of the first difference is greater than or equal to 0.05 eV and less than or equal to 0.1 eV, and the absolute value of the second difference is greater than or equal to 0.1 eV and less than or equal to 0.15 eV.

9. The light-emitting device according to claim 8, wherein the green light-emitting layer comprises green light-emitting host material and green light-emitting dopant material, the average activation energy of the energy level adjustment layer and an average activation energy of the green light-emitting dopant material have a third difference therebetween, and an absolute value of the third difference is less than 0.05 eV.

10. The light-emitting device according to claim 9, wherein an absolute value of a difference between an average activation energy of the green light-emitting host material and the average activation energy of the green light-emitting dopant material is in a range of 0.08-0.12 eV.

11. The light-emitting device according to claim 1, wherein the light-emitting layer comprises a red light-emitting layer, the absolute value of the first difference is greater than or equal to 0.1 eV and less than or equal to 0.15 eV, and the absolute value of the second difference is less than 0.05 eV.

12. The light-emitting device according to claim 11, wherein the red light-emitting layer comprises red light-emitting host material and red light-emitting dopant material, a third difference exists between the average activation energy of the energy level adjustment layer and an average activation energy of the red light-emitting dopant material, and an absolute value of the third difference is less than 0.05 eV.

13. The light-emitting device according to claim 12, wherein an absolute value of a difference between an average activation energy of the red light-emitting host material and the average activation energy of the red light-emitting dopant material is in a range of 0.08-0.12 eV.

14. The light-emitting device according to claim 1, wherein the energy level adjustment layer comprises an electron-blocking layer.

15. The light-emitting device according to claim 14, further comprising a first energy level layer located between the electron-blocking layer and the light-emitting layer, wherein an average activation energy of the first energy level layer is between an average activation energy of the electron-blocking layer and the average activation energy of the host material in the light-emitting layer.

16. The light-emitting device according to claim 14, further comprising a second energy level layer located between the electron-blocking layer and the hole transport layer, wherein an average activation energy of the second energy level layer is between an average activation energy of the electron-blocking layer and the average activation energy of the hole transport layer.

17. The light-emitting device according to claim 14, further comprising:
an energy-level-matching layer, located on a side of the light-emitting layer away from the energy level adjustment layer; and
an electron transport layer, located on a side of the energy-level-matching layer away from the light-emitting layer;
wherein the energy-level-matching layer comprises a hole-blocking layer, an average activation energy of the electron transport layer and an average activation energy of the energy-level-matching layer have a fourth difference therebetween, the average activation energy of the energy-level-matching layer and the average activation energy of the host material in the light-emitting layer have a fifth difference therebetween, and an absolute value of the fourth difference is less than an absolute value of the fifth difference.

18. The light-emitting device according to claim 17, wherein the light-emitting layer comprises a blue light-emitting layer, the absolute value of the fourth difference is less than 0.05 eV, and the absolute value of the fifth difference is greater than or equal to 0.1 eV and less than or equal to 0.15 eV.

19. The light-emitting device according to claim 18, wherein the blue light-emitting layer comprises blue light-emitting host material and blue light-emitting dopant material, an average activation energy of the blue light-emitting dopant material and the average activation energy of the energy-level-matching layer have a sixth difference therebetween, and an absolute value of the sixth difference is less than the absolute value of the fifth difference.

20. A display panel, comprising an array substrate, a light-emitting device layer, an encapsulation layer arranged in a stacked manner, wherein the light-emitting device layer comprises a light-emitting device;
wherein the light-emitting device comprises a hole transport layer, an energy level adjustment layer and a light-emitting layer arranged in a stacked manner, wherein an average activation energy of the hole transport layer and an average activation energy of the energy level adjustment layer have a first difference therebetween, the average activation energy of the energy level adjustment layer and an average activation energy of main body material in the light-emitting layer have a second difference therebetween, and an absolute value of the first difference and an absolute value of the second difference are greater than 0 eV.
